(19) United States
(12) Patent Application Publication
(10) Pub. No.: US 2008/0272384 A1
(43) Pub. Date: Nov. 6, 2008

(54) Light emitting diode

(75) Inventors: Ting-Tung Cheng, Bade City (TW); Wen-Pao Tseng, Bade City (TW); Hsin-Chien Chiang, Bade City (TW)

Correspondence Address: TROXELL LAW OFFICE PLLC, SUITE 1404, 5205 LEESBURG PIKE, FALLS CHURCH, VA, 22041, US

(73) Assignee: ADO OPTRONICS CORPORATION

(21) Appl. No.: 11/797,647

(22) Filed: May 4, 2007

(51) Int. Cl. H01L 33/00

(52) U.S. Cl. 257/98; 257/E33.061

(57) ABSTRACT

A light emitting diode (LED) having disposed on a top of a package an optical mechanism comprised of multiple grooves or dots to promote optical use efficiency of the packaging through light condensing effects produced by the optical mechanism to collect a light source inside the LED to emit in a given direction through the optical mechanism for effectively reducing discriminating escape of the light source in both right and left sides of the given direction thus to significantly upgrade general luminance performance of the LED.

### BACKGROUND OF THE INVENTION

(a) Field of the Invention

The present invention is related to a light emitting diode, and more particularly to one with improved packaging construction to upgrade the luminance performance of the light emitting diode.

(b) Description of the Prior Art

A light emitting diode (LED) related to a semiconductor device that releases energy in a form of light by incorporation among electronic holes is comprehensively applied in electric appliances, information billboards, and communication products due to the LED features cold light emission to provide advantages including compact size, long service life, low power consumption, fast responsive rate, and good shock absorption.

The LED is essentially comprised of having a gold plated wire provided for connecting a light-emitting chip (i.e., a semiconductor chip) to its associate circuits; the light-emitting chip is then packed in a packaging material to make the light-emitting chip a package with mechanical strength; once the light-emitting chip is electrically conducted, it generates light source and outwardly radiates through the package or the light source of the light-emitting chip is incorporated with a wave length of an effect material (e.g., a fluorescent material) in the packaging material to produce an expected light color.

Therefore, a diffusion feature (light utility) of the package wrapping up the exterior of the light-emitting chip on the light source is sufficient to affect the performance of luminance of the LED as a general. Improving the light utility of the package achieves the purpose of upgrading the luminance performance of the LED.

### SUMMARY OF THE INVENTION

The primary purpose of the present invention is to provide a construction of an LED that significantly upgrades overall luminance performance of the LED by effectively reducing indiscriminating escape of a light source in both right and left directions. To achieve the purpose, an optical mechanism comprised of multiple grooves or dots is disposed on a top of a package of the LED to increase light use efficiency of the package through light condensing effects produced by the optical mechanism. That is, the light source in the LED is collected to radiate in a given direction through the optical mechanism to effectively reduce indiscriminating escape of the light source towards both of the left and the right sides of the light source thus to significantly upgrade the overall luminance performance of the LED.

### BRIEF DESCRIPTION OF THE DRAWINGS

FIG. 1 is a perspective view showing an appearance of an LED of a first preferred embodiment of the present invention.

FIG. 2 is a sectional view of the first preferred embodiment of the present invention.

FIG. 3 is a magnified view showing multiple V-shaped grooves in the present invention.

FIG. 4 is a sectional view of an LED of a second preferred embodiment of the present invention.

FIG. 5 is a sectional view of an LED of a third preferred embodiment of the present invention.

FIG. 6 is a sectional view of an LED of a fourth preferred embodiment of the present invention.

FIG. 7 is a sectional view of an LED of a fifth preferred embodiment of the present invention.

FIG. 8 is a perspective view of the fourth preferred embodiment of the present invention.

FIG. 9 is a sectional view of an LED of a sixth preferred embodiment of the present invention.

FIG. 10 is a sectional view of an LED of an eighth preferred embodiment of the present invention.

### DETAILED DESCRIPTION OF THE PREFERRED EMBODIMENTS

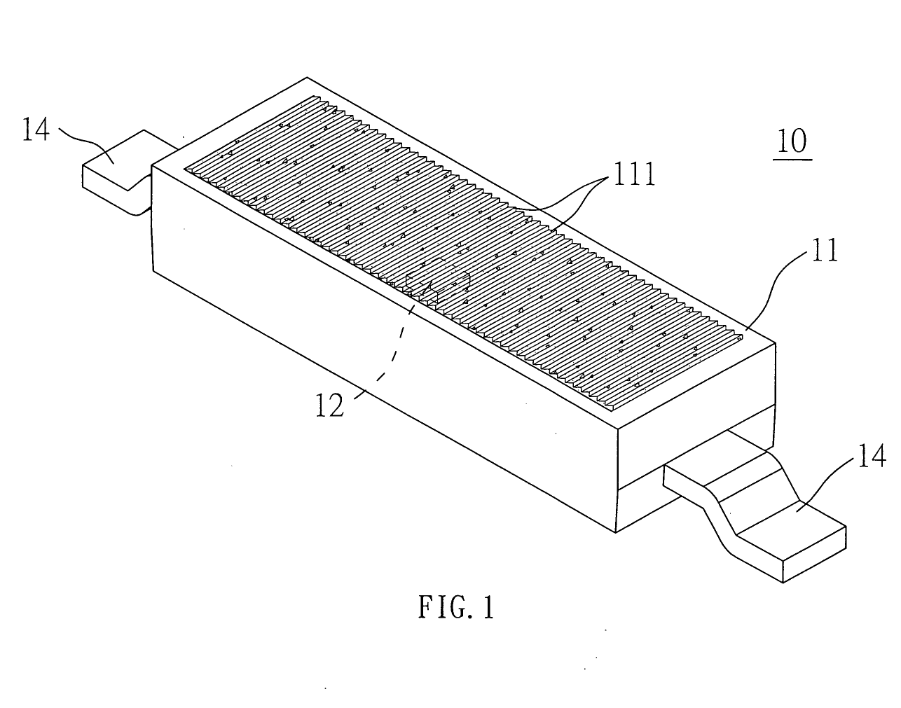

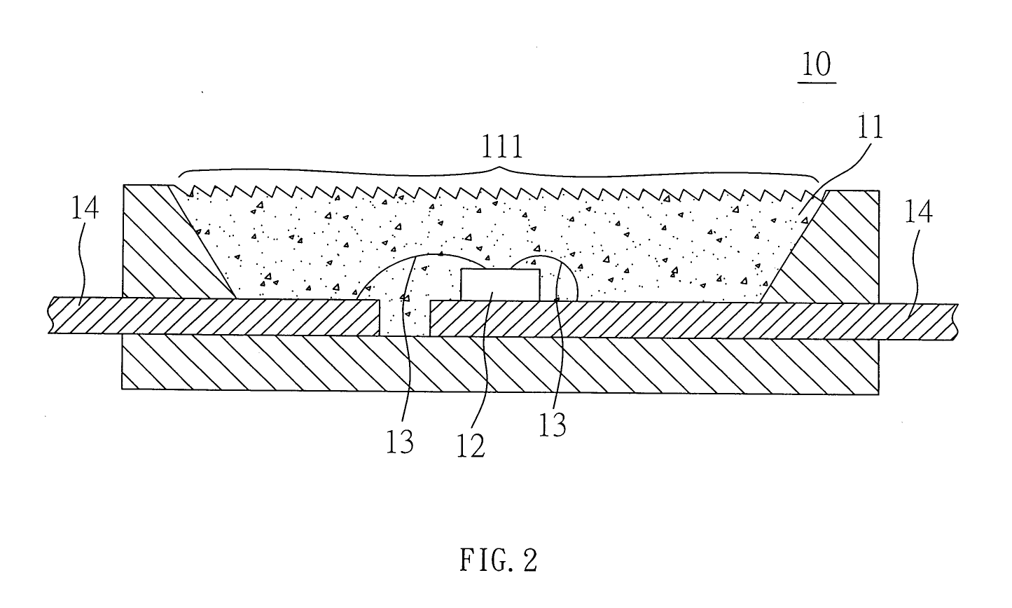

Referring to FIGS. 1 and 2, a light emitting diode 10 of a first preferred embodiment is essentially comprised of having a gold plated wire 13 to electrically connect a light-emitting chip 12 and its associate circuit pins 14; a packaging material is place on top of the light-emitting chip 12 to pack the light-emitting chip 12 into a package 11 provided with mechanical strength for a light source generated from the light-emitting chip to externally radiate through the package 11.

An optical mechanism 111 to produce light condensation is disposed on a top of the package 11 for increase light use efficiency of the package 11. Accordingly, the light source inside the LED 10 is collected and radiates in a given direction through the optical mechanism 111 to effectively reduce indiscriminating escape of the light source to both of the right and the left direction of the light source thus to significantly upgrade overall luminance performance of the LED.

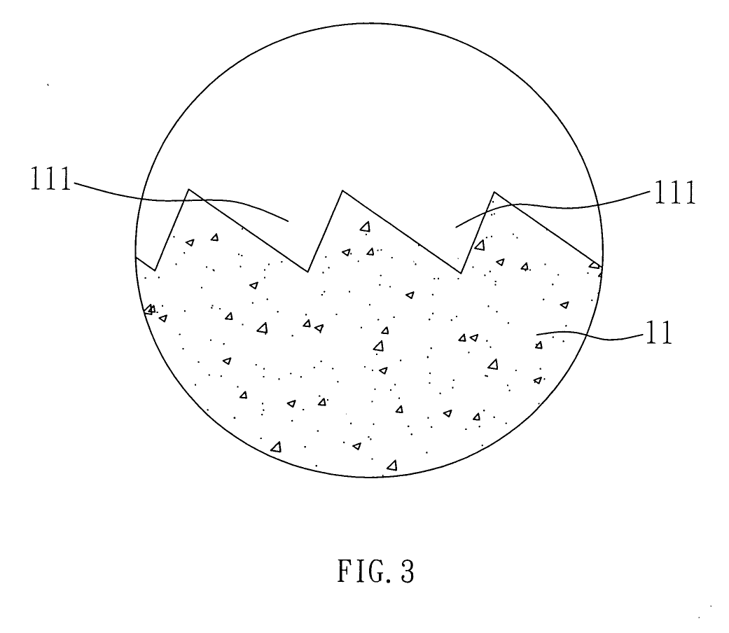

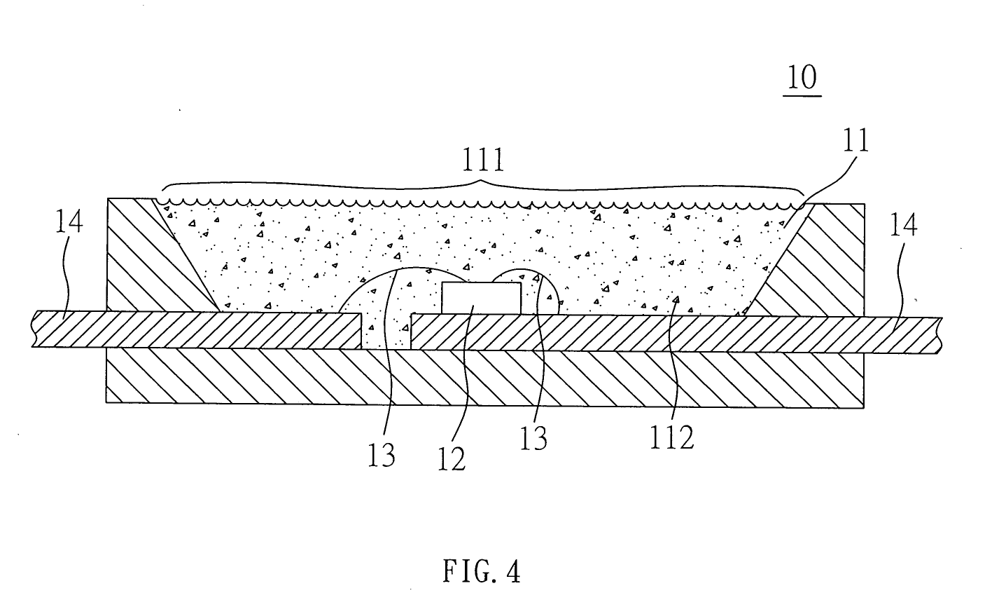

The optical mechanism 111 disposed on the top of the package 111 as illustrated in FIGS. 1 and 2 is comprised of multiple V-shaped grooves. Each V-shaped groove as illustrated in FIG. 3 is comprised of two sides of different angles so that two not-isogonal light emerging planes are defined between any two abutted grooves 111; or alternatively, as illustrate din FIG. 4, the optical mechanism 111 disposed at the top of the package 11 is comprised of multiple arc grooves and multiple curved surfaces cut by those arc grooves serve the light emerging plane of the LED.

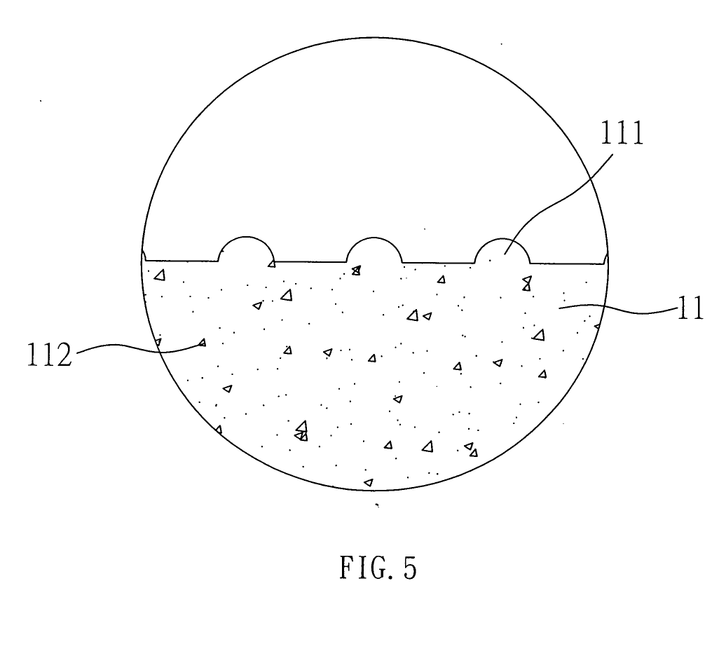

As illustrated in FIG. 5, the same light condensation can be achieved by having the optical mechanism 111 comprised of multiple protruding dots on a surface of the package 11 for the light source inside the LED to be collected and radiate in a given direction through the optical mechanism 111 thus to correct discriminating escape of the light source towards its right and left directions.

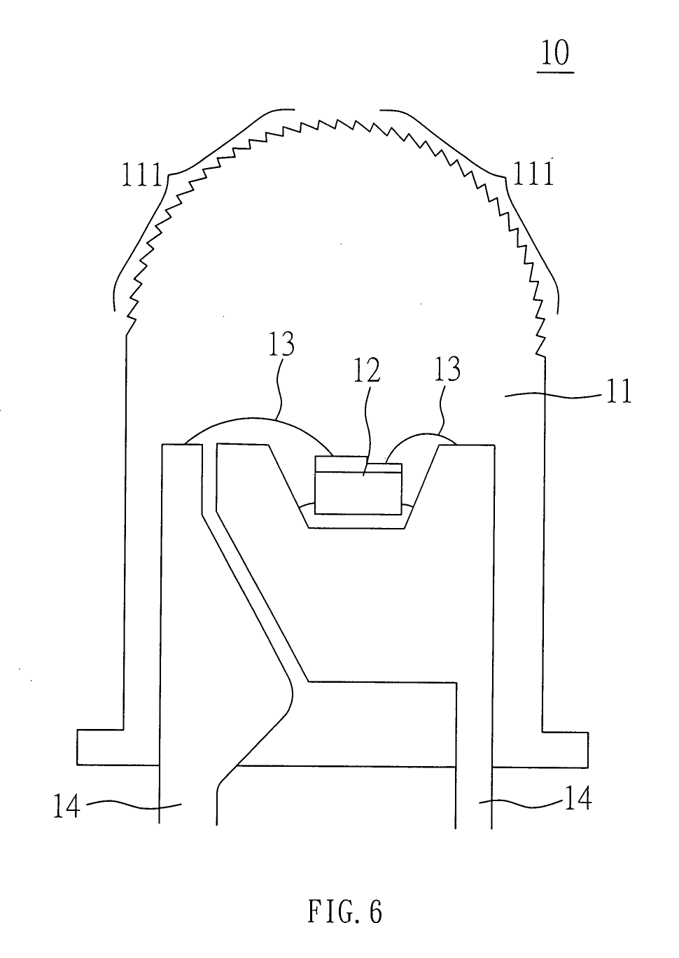

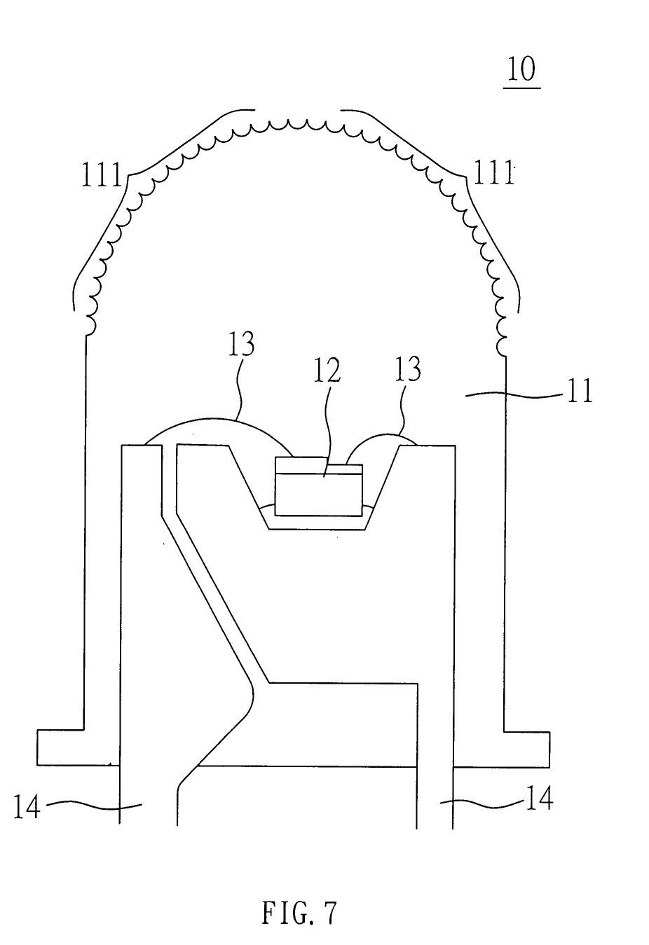

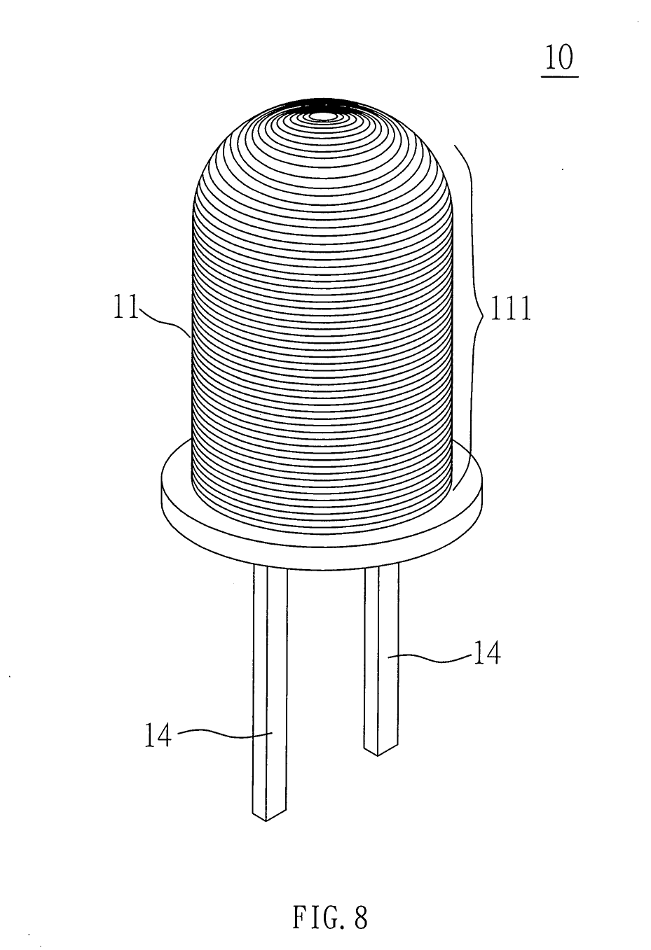

In both of the first and the second preferred embodiments, the top of the package 11 of the LED 10 is made flat and it is preferred that the optical mechanism 111 is built up on the top of the entire package 11 so to upgrade luminance performance of the LED and to present consistent luminance for an entire light emitting area of the LED. Furthermore, if and when the top of the package 11 of the LED 10 as illustrated in FIGS. 6, 7, and 8 is made in a spherical form, the optical mechanism is preferred to be built up on and entire spherical region on the top of the package 11 to achieve consistent luminance performance of an entire light emitting region for the LED.

Improvement made by the present invention to have the optical mechanism built upon top of the package for collecting the light source in the LED and externally radiating in a given direction through the optical mechanism effectively reduce indiscriminating escape of the light source to both of the right and left direction of the light source thus to significantly upgrade overall luminance performance of the LED in achieving consistent luminance performance in the light emitting region of the LED.

Multiple diffusion grains 112 are further disposed in the package 11 as illustrated in FIGS. 4 and 5 for light streams emitted form the light-emitting chip 12 to increase their refraction angles through each diffusion grain 112.

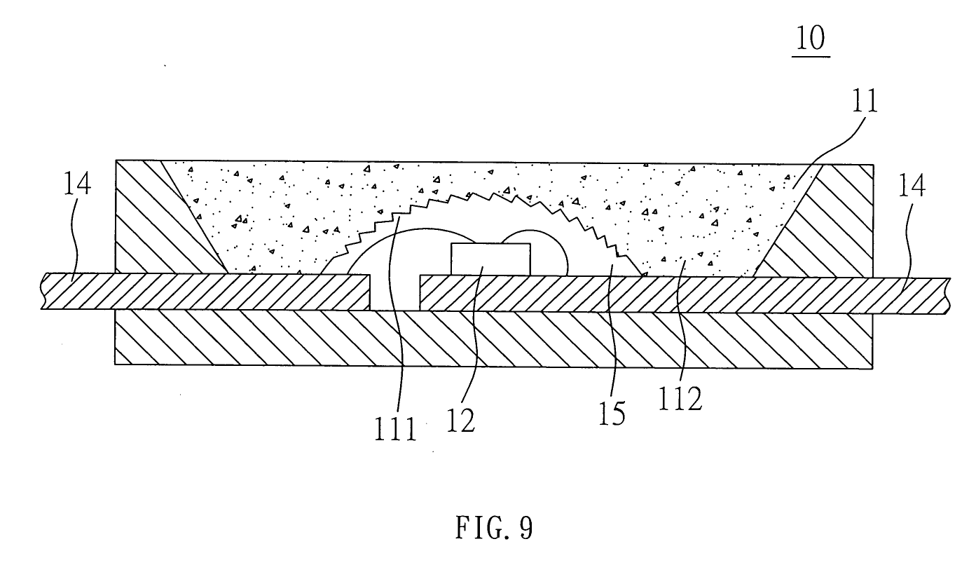

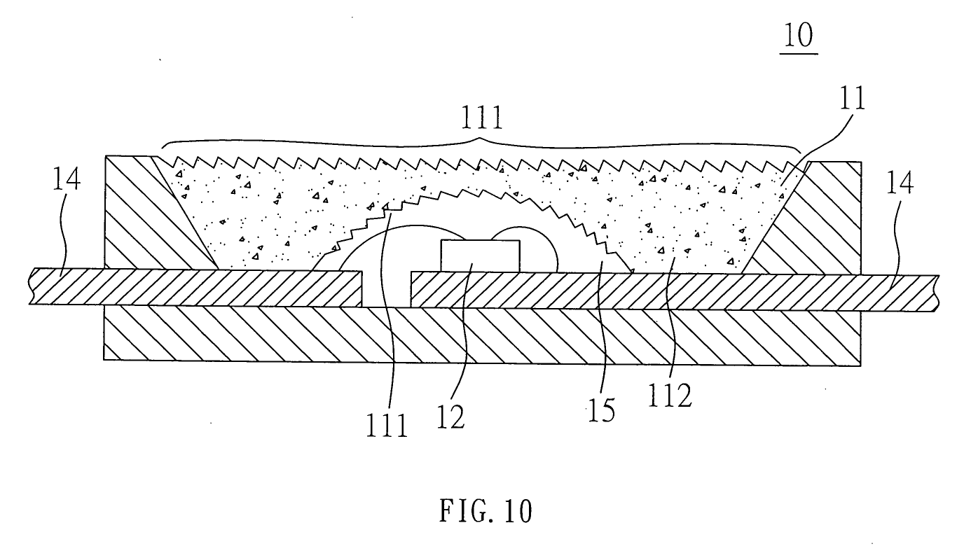

Now referring to FIG. 9 for a sixth preferred embodiment of the present invention, an air layer 15 is defined between the light-emitting chip 12 and the package 11; and the optical mechanism 111 for light condensation is disposed at where close to the air layer 15. Alternatively as illustrated in FIG. 10, the optical mechanism 111 comprised of multiple V-shaped grooves with each including two sides at different angles, arc grooves, or protruding dots to achieve the same purpose of correcting the discriminating escape of the light source towards its right and left directions.

It is to be noted that the preferred embodiments disclosed in the specification and the accompanying drawings are not limiting the present invention; and that any construction, installation, or characteristics that is same or similar to that of the present invention should fall within the scope of the purposes and claims of the present invention.

I claim:

1. An improved construction of a light emitting diode including an optical mechanism disposed on a top of a package of the LED and comprised of multiple V-shaped grooves with each having two sides at different angles; and two non-isogonal light emerging planes being defined by any two abutted V-shaped grooves.

2. The improved construction of the light emitting diode as claimed in claim 1, wherein the top of the package is made in a flat form.

3. The improved construction of the light emitting diode as claimed in claim 1, wherein the top of the package is made in a spherical form.

4. The improved construction of the light emitting diode as claimed in claim 1, wherein the package contains multiple diffusion grains.

5. An improved construction of a light emitting diode including an optical mechanism built upon a top of a package and comprised of multiple arc grooves; and a light emerging plane to cut into a light emerging place comprised of multiple curved surfaces.

6. The improved construction of the light emitting diode as claimed in claim 5, wherein the top of the package is made in a flat form.

7. The improved construction of the light emitting diode as claimed in claim 5, wherein the top of the package is made in a spherical form.

8. The improved construction of the light emitting diode as claimed in claim 5, wherein the package contains multiple diffusion grains.

9. An improved construction of a light emitting diode including an optical mechanism built upon a top of a package and comprised of multiple arc grooves; and the optical mechanism being comprised of multiple protruding dots built on a surface of the package.

10. The improved construction of the light emitting diode as claimed in claim 9, wherein the top of the package is made in a flat form.

11. The improved construction of the light emitting diode as claimed in claim 9, wherein the top of the package is made in a spherical form.

12. The improved construction of the light emitting diode as claimed in claim 9, wherein the package contains multiple diffusion grains.

13. An improved construction of a light emitting diode including a light-emitting chip electrically connected to its associate circuit pins by means of a gold plated wire; a package disposed on top of the light-emitting chip to pack the light-emitting chip; an air layer disposed between the light-emitting chip and the package; and an optical mechanism disposed to the package at where close to the air layer for light condensation.

14. The improved construction of the light emitting diode as claimed in claim 13, wherein the optical mechanism is comprised of multiple V-shaped grooves with each having two sides of different angles.

15. The improved construction of the light emitting diode as claimed in claim 13, wherein the optical mechanism is comprised of multiple arc grooves.

16. The improved construction of the light emitting diode as claimed in claim 13, wherein the optical mechanism is comprised of multiple protruding dots built upon on a surface of the package.
